(19) United States
(12) Patent Application Publication
(10) Pub. No.: US 2012/0222718 A1
(43) Pub. Date: Sep. 6, 2012

(54) PHOTOVOLTAIC GROUNDING & BONDING CONNECTOR

(75) Inventor: Thomas M. Sweeney, Cincinnati, OH (US)

(73) Assignee: ILSCO CORPORATION, Cincinnati, OH (US)

(21) Appl. No.: 13/409,472

(22) Filed: Mar. 1, 2012

Related U.S. Application Data
(60) Provisional application No. 61/448,238, filed on Mar. 2, 2011.

(51) Int. Cl. H01L 31/042; H01R 13/40; H01R 43/20

(52) U.S. Cl. 136/244; 29/876; 439/733.1

(57) ABSTRACT

A photovoltaic (PV) panel and rack grounding connector may be constructed of a one piece extruded aluminum body. The body may have two extruded openings configured to accept a ground wire at one end and a PV panel or rack flange at the other. Both openings may have extruded serrations to pierce oxidation on the wire end and anodized plating on the PV panel or rack end. Stainless steel or other screws are provided on each end of the connector for securing the wire and panel, respectively, to the connector and to prevent corrosion. The connector may be asymmetric in that the opening on one end for the ground wire is a different shape than the opening on the opposite end for the PV panel.

This claims priority to U.S. Provisional Patent Application Ser. No. 61/448,238, filed Mar. 2, 2011 and hereby incorporated by reference in its entirety.

### BACKGROUND OF THE INVENTION

Photovoltaic (PV) panels or arrays produce electricity from solar energy. Electrical power produced by PV panels reduces the amount of energy required from non-renewable resources such as fossil fuels and nuclear energy. Significant environmental benefits are also realized from solar energy production, for example, reduction in air pollution from burning fossil fuels, reduction in water and land use from power generation plants, and reduction in the storage of waste byproducts. Solar energy produces no noise, and has few moving components. Because of their reliability, PV panels also reduce the cost of residential and commercial power to consumers.

PV cells are essentially large-area semiconductor diodes. Due to the photovoltaic effect, the energy of photons is converted into electrical power within a PV cell when the PV cell is irradiated by a light source such as sunlight. PV cells are typically interconnected into solar panels that have power ranges of up to 100 watts or greater. For large PV systems, special PV panels are produced with typical power ranges of up to several 100 watts. A PV panel is the basic element of a photovoltaic power generation system. A PV panel has many solar cells interconnected in series or parallel, according to the desired voltage and current parameters. PV cells are connected and placed between a polyvinyl plate on the bottom and a tempered glass on the top. PV cells are interconnected with thin contacts on the upper side of the semiconductor material. The typical crystalline panel's power ranges from several watts to up to 200 watts/panel.

In the case of facade or roof systems the PV system may be installed during construction, or added to the building after it is built. Roof systems are generally lower powered systems, e.g., 10 kW, to meet typical residential loads. Roof integrated PV systems may consist of different panel types, such as crystalline and micro-perforated amorphous panels. Roof-integrated PV systems are integrated into the roof; such that the entire roof or a portion thereof is covered with PV panels, or they are added to the roof later. PV cells may be integrated with roof tiles or shingles.

PV panels and arrays of panels require specially designed devices adapted for interconnecting the various PV panels with each other, and with electrical power distribution systems. PV connection systems are used to accommodate serial and parallel connection of PV arrays. In addition to connection boxes, a PV connection system includes connectors that allow for speedy field installation or high-speed manufacture of made-to-length cable assemblies. Connectors or connection boxes may be required to receive specialized cable terminations from PV panels/arrays, with power diodes inside for controlling current flow to the load. PV arrays may be required in areas with tight space restraints and requirements, requiring the size of the PV panel to be minimized and the ease of PV panel connection maximized.

Various clamping devices are known for providing an electrical, grounding and mechanical connection from an electrical wire to a plate such as a PV panel. Drilling a hole through a portion of the PV panel is highly undesirable in that it may allow foreign matter and moisture into the box, can create a safety problem due to high voltage, can allow corrosion of the metal, and/or may be contrary to local codes.

Because of various code requirements, there should be a separate screw for connecting an electrical wire to the connector in addition to any clamping screw(s) for connecting the connector to the PV panel.

To provide grounding protection, the connector must be able to withstand a fusion test in which high current is passed through the connector for a predetermined time. Different users as well as standards setting organizations have different requirements. The connector must survive certain current surges to the extent that a #6AWG solid copper wire connected to the clamp and through which the current is passing will fuse before the integrity of the clamp is compromised.

Because of adverse weather conditions, it is very important for the connector to be rugged, as well as capable of forming and maintaining over time a secure mechanical and electrical connection to the PV panel. In addition, the connector should be inexpensively formed with minimum parts and be capable of simple installation.

What is needed is a connector for a PV solar array panel that satisfies one or more of these space constraint limitations or provides other advantageous features. Other features and advantages will be made apparent from the present specification. The teachings disclosed extend to those embodiments that fall within the scope of the claims, regardless of whether they accomplish one or more of the aforementioned needs.

### SUMMARY OF THE INVENTION

In various embodiments, this invention is a new photovoltaic (PV) panel and rack grounding connector which may be constructed of a one piece extruded aluminum body. The body may have two extruded openings configured to accept a ground wire at one end and a PV panel or rack flange at the other. Both openings may have extruded serrations to pierce oxidation on the wire and anodized plating on the PV panel or rack end. Stainless steel or other screws are provided on each end of the connector for securing the wire and panel, respectively, to the connector and to prevent corrosion. The PV connector may be asymmetric in that the opening on one end for the ground wire is a different shape than the opening on the opposite end for the PV panel.

Various advantages of the connector according to embodiments of this invention include Underwriter's Laboratory (UL) and Canadian Standards Association (CSA) approvals for use in grounding and bonding, specifically aimed at PV panels, racks and frames. The PV connector may be dual rated for aluminum and copper wire (stranded or solid) while prior art products are rated for copper only. Since PV installations are always an outdoor application, the use of aluminum ground wire would eliminate galvanic corrosion.

Additionally, no mounting hardware is required for attachment of the connectors to the PV panel according to embodiments of this invention in that mounting screws are included with the PV connector. Moreover, drilling a mounting hole in the PV panel is not required as is needed with prior art PV connectors. No surface preparation is required for installation; extruded serrations on various embodiments of the PV connector penetrate both an anodized finish and corrosion. The lay in wireway design of the connector allows ground and bond wires to be continuous thereby avoiding the time consuming and tedious tasks of splicing or forming connections between the wires. The slot on the connector for the PV panel or frame also employs the “lay in” concept.

Another aspect of various embodiments of this invention is that the connector body acts like a spring clamp to maintain pressure on the PV panel and/or the wire. The PV connector body is sufficiently robust in various embodiments to deflect under loads without resulting in permanent deflection of the PV connector body while still maintaining a secure mount and connection.

### BRIEF DESCRIPTION OF THE DRAWINGS

The above-mentioned and other features and advantages of this invention, and the manner of attaining them, will become more apparent and the invention itself will be better understood by reference to the following description of embodiments of the invention taken in conjunction with the accompanying drawings, wherein:

FIG. 1 is a perspective view of one embodiment of a PV connector joined to a wire cable and the edge of a PV panel in a PV installation;

FIG. 2 is a view similar to FIG. 1 without the cable and panel shown;

FIG. 3 is a cross-sectional view of the connector of FIG. 1;

FIG. 4 is a perspective view of another embodiment of a PV connector according to this invention; and

FIG. 5 is a cross-sectional view taken along line 5-5 of FIG. 4.

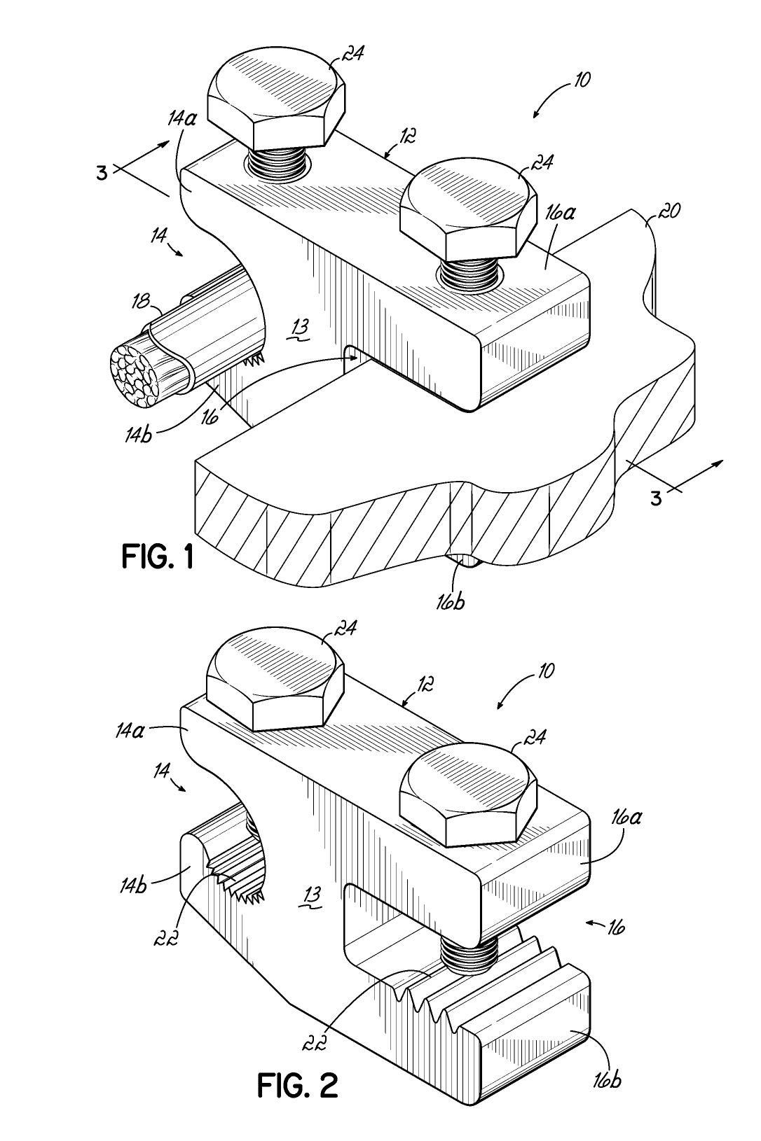

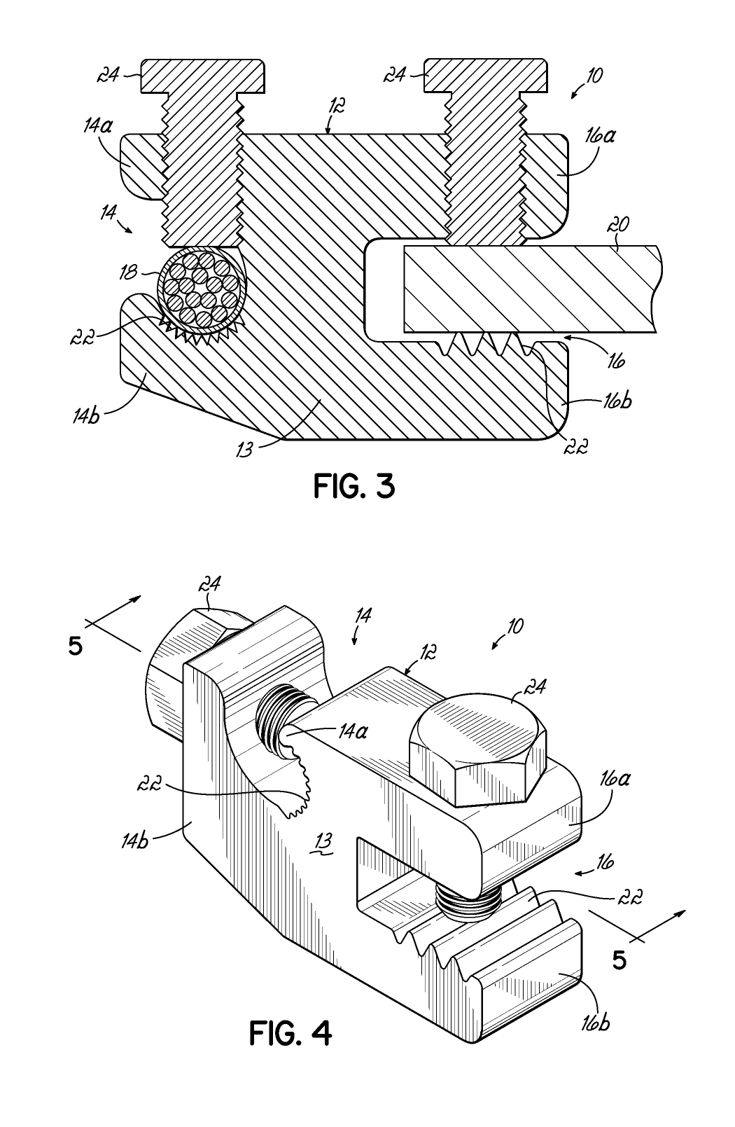

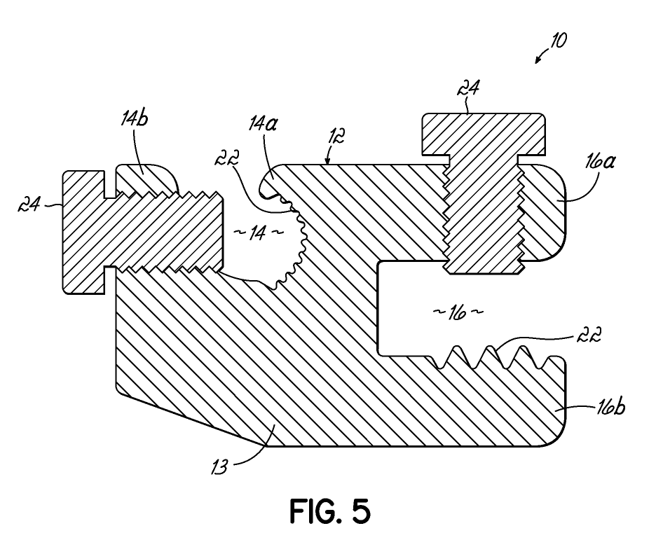

### DETAILED DESCRIPTION OF THE INVENTION

This invention in various embodiments is a new photovoltaic (PV) panel and rack grounding connector 10 with a one piece extruded aluminum body 12. The PV connector is used in a PV collection installation. The body 12 has two openings 14, 16 formed by respective arms 14a, 14b and 16a, 16b extending from a central body 13. The connector 10 is configured to accept a ground wire or conductor 18 at one end and a PV panel or rack flange 20 at the other. Both openings 14, 16 may be extruded and have extruded serrations 22 to pierce oxidation on the wire end and anodized plating on the PV panel or rack flange 20. Stainless steel screws 24 are provided on each end of the connector 10 and are threadably mounted in respective threaded holes in the connector 10 for securing the wire 18 and panel 20, respectively, to the connector 10 and to prevent corrosion. The connector 10 in one embodiment is asymmetric in that the opening 14 on one end for the ground wire 18 is a different shape than the opening 16 on the opposite end for the PV panel 20.

Embodiments of the invention provide a PV electrical connector configured to maintain an electrical and/or grounding connection with a PV panel during various heating and cooling cycles. In one embodiment, the PV connector 10 includes one or more compliant arms 14a, 14b, 16a, 16b configured to deflect and provide a compressive spring force to a fastener 24 in contact with the attached panel 20 or wire 18. This invention is directed to a PV connector 10 that mounts to the edge of the PV panel 20 in an array of such panels 20. In a PV collection system, the panels 20 are disposed side by side to form an array of PV panels 20 and the connector 10 grounds the array to the connected conductor or wire 18. The PV connector 10 may be of a size or dimensions suitable for the array.

Advantages of the PV connector 10 include UL and CSA approvals for use in grounding and bonding, specifically aimed at PV panels 20, racks and frames. The connector 10 may be dual rated for aluminum and copper wire 18 (stranded or solid) while other products are rated for copper only. Since PV installations are always an outdoor application, the use of aluminum ground wire would eliminate galvanic corrosion. Additionally, no mounting hardware or drilling is required for attachment of the connector 10 to the PV panel 20; a mounting screw 24 is included. Moreover, drilling a mounting hole in the PV panel 20 is not required. No surface preparation is required for installation; extruded serrations 22 on one or more of the arms 14a, 14b, 16a, 16b penetrate both an anodized finish and corrosion. The lay in wireway slot 14 and panel slot 16 design of the PV connector 10 allows ground and bond wires to be continuous. The slot 16 for the PV panel or frame 20 also employs the “lay in” concept.

The PV connector 10 body acts like a spring clamp to maintain pressure. The PV connector body 13 is sufficiently beefy to deflect without taking permanent deflection. The spaced arms 14a, 14b, 16a, 16b which form the slots 14, 16 are cantilevered outwardly from the central body 13 of the connector 10 and are configured to move and/or flex to accommodate the expansion or contraction of the connector 10 as it may cyclically heat and cool. PV connector 10 is configured to provide and maintain an electrical and/or grounding connection with a conductor 18 and/or panel 20 inserted into the respective slot 14, 16. Suitable materials for the PV connector 10 generally include electrically conductive metals that will deflect under the force of fastener 24 to provide a return spring force. One suitable material for fabrication of PV connector 10 is aluminum, although other metals such as copper, alloys of copper, alloys of aluminum, or bronze are also acceptable. Fastener 24 includes any suitable fastener configured to interlock with the conductor 18 and/or panel 20 and provide sufficient compression there against when such is inserted into slot 14, 16 in a manner that will deflect one or both of the arms 14a, 14b, 16a, 16b forming the slot 14, 16 One suitable fastener 24 includes a hex-head socket threaded fastener, although other suitable fasteners such as bolts and the like are also acceptable. In one embodiment, fastener 24 is selected to have similar electrical properties and a similar coefficient of thermal expansion as the body 13 of the connector 10. One suitable material for fastener 24 is aluminum, although other metals such as bronze, stainless steel and copper are also suitable.

While not bound to any particular theory of operation, it is believed that the energy employed in securing fastener 24 against conductor 18 and/or panel 20 is stored in the arms 14a, 14b, 16a, 16b of the connector 10, which are deflected in a manner that provides a spring force (and thereby stores spring energy) to the arms that is transferred through fastener 24 into conductor 18 and/or panel 20.

Heating and cooling cycles of connector 10 can be expected to thermally expand and contract the body 13. Arms 14a, 14b, 16a, 16b, however, provide a spring force that compliantly secures fastener 24 against conductor 18 and/or panel 20 during the heating and cooling cycles and maintains an electrical/grounding connection between conductor 18 and/or panel 20 and body 13. The arms 14a, 14b, 16a, 16b are configured to deflect when fasteners 24 are tightened against the conductors 18 or panel 20 in a manner that provides a spring force that compliantly secures fasteners 24 there against.

From the above disclosure of the general principles of this invention and the preceding detailed description of at least one embodiment, those skilled in the art will readily comprehend the various modifications to which this invention is susceptible. Therefore, I desire to be limited only by the scope of the following claims and equivalents thereof.

I claim:

1. A photovoltaic collection system comprising:
a plurality of photovoltaic panels each having an edge;
a ground wire;
a plurality of connectors each coupled to one of the panels and to the ground wire;
wherein each of the connectors further comprises,
(a) a connector body,
(b) a first and a second slot formed in the connector body wherein the ground wire is seated within the first slot and the edge of the associated photovoltaic panel is seated in the second slot; and
(c) a first and a second fastener coupled to the connector body, the first fastener securing the ground wire in the first slot and the second fastener securing the edge in the second slot.

2. The photovoltaic collection system of claim 1 wherein the first and second slots are formed between a first and a second pair of arms, respectively, projecting from the connector body.

3. The photovoltaic collection system of claim 2 wherein at least one of the arms is configured to deflect to provide a spring force that secures the respective fastener against the edge or the ground wire during heating/cooling cycles.

4. The photovoltaic collection system of claim 1 wherein the first and second slots are oriented on opposite ends of the connector body approximately 180° apart.

5. The photovoltaic collection system of claim 1 wherein the first and second slots are oriented approximately 90° on the connector body.

6. The photovoltaic collection system of claim 1 further comprising:
a plurality of serrations in at least one of the first and second slots with the associated fastener oriented opposite from the serrations.

7. The photovoltaic collection system of claim 1 wherein each connector is generally asymmetric about a plane dividing the first and second slots.

8. The photovoltaic collection system of claim 1 wherein each connector is generally asymmetric about a plane containing the first and second slots.

9. A photovoltaic collection system comprising:
a plurality of photovoltaic panels each having a perimeter edge;
a ground wire;
a plurality of connectors each coupled to one of the panels and to the ground wire;
wherein each of the connectors further comprises,
(a) a connector body,
(b) a first and a second slot formed in the connector body wherein the ground wire is seated within the first slot and the edge of the associated photovoltaic panel is seated in the second slot;
(c) the first and second slots being formed between a first and a second pair of arms, respectively, projecting from the connector body;
wherein at least one of the arms is configured to deflect to provide a spring force that secures the respective fastener against the edge or the ground wire during heating/cooling cycles;
(d) a first and a second fastener coupled to the connector body, the first fastener securing the ground wire in the first slot and the second fastener securing the edge in the second slot; and
(e) a plurality of serrations in at least one of the first and second slots with the associated fastener oriented opposite from the serrations
wherein each connector is generally asymmetric about a plane dividing the first and second slots;
wherein each connector is generally asymmetric about a plane containing the first and second slots.

10. The photovoltaic collection system of claim 9 wherein the first and second slots are oriented on opposite ends of the connector body approximately 180° apart.

11. The photovoltaic collection system of claim 9 wherein the first and second slots are oriented approximately 90° on the connector body.

12. A connector for a photovoltaic collection system having a plurality of photovoltaic panels each having a perimeter edge and a ground wire coupled to each of the photovoltaic panels, the connector comprising:
a connector body,
a first and a second slot formed in the connector body wherein the ground wire is seated within the first slot and the edge of the associated photovoltaic panel is seated in the second slot; and
a first and a second fastener coupled to the connector body, the first fastener securing the ground wire in the first slot and the second fastener securing the edge in the second slot.

13. The connector of claim 12 wherein the first and second slots are formed between a first and a second pair of arms, respectively, projecting from the connector body.

14. The connector of claim 13 wherein at least one of the arms is configured to deflect to provide a spring force that secures the respective fastener against the edge or the ground wire during heating/cooling cycles.

15. The connector of claim 12 wherein the first and second slots are oriented on opposite ends of the connector body approximately 180° apart.

16. The connector of claim 12 wherein the first and second slots are oriented approximately 90° on the connector body.

17. The connector of claim 12 further comprising:
a plurality of serrations in at least one of the first and second slots with the associated fastener oriented opposite from the serrations.

18. The connector of claim 12 wherein each connector is generally asymmetric about a plane dividing the first and second slots.

19. The connector of claim 12 wherein each connector is generally asymmetric about a plane containing the first and second slots.

20. A method of connecting a photovoltaic panel to a ground wire comprising the steps of:
inserting an edge of the photovoltaic panel into a first slot formed between a first pair of arms on a connector;
securing the edge of the photovoltaic panel into the first slot with a first fastener threadably coupled to the connector;
deflecting one of the first pair of arms during the securing step to thereby provide a spring force that urges the first fastener against the edge during heating/cooling cycles;
piercing through a layer of anodized plating on the panel with serrations formed in one of the arms of the first pair of arms on the connector;
inserting a ground wire into a second slot formed between a second pair of arms on the connector;
securing the ground wire into the second slot with a second fastener threadably coupled to the connector; and
piercing through a layer of oxidation on the ground wire with serrations formed in one of the arms of the second pair of arms on the connector.
